(19) United States
(12) Patent Application Publication
(10) Pub. No.: US 2017/0206972 A1
(43) Pub. Date: Jul. 20, 2017

(54) LATCH CIRCUIT AND SEMICONDUCTOR MEMORY DEVICE

(71) Applicant: Powerchip Technology Corporation, Hsinchu (TW)

(72) Inventor: Akitomo Nakayama, Tokyo (JP)

(73) Assignee: Powerchip Technology Corporation, Hsinchu (TW)

(21) Appl. No.: 15/247,898

(22) Filed: Aug. 25, 2016

(30) Foreign Application Priority Data
Jan. 19, 2016 (JP) 2016-007605

(51) Int. Cl. G11C 16/26; G11C 16/08; G11C 16/14; G11C 16/10

(52) U.S. Cl. CPC G11C 16/26; G11C 16/10; G11C 16/08; G11C 16/14

(57) ABSTRACT

A latch circuit provided herein includes an input circuit including a PMOS transistor that is configured for input and enables a signal current to flow into the PMOS transistor; a first inverter comprising a first PMOS transistor, a first NMOS transistor, and a first node; a second inverter comprising a second PMOS transistor, a second NMOS transistor, and a second node. The signal current corresponds to a sense voltage from a sense amplifier. The first PMOS transistor and the first NMOS transistor are connected to each other through the first node, and the first node is connected to the input circuit. The second PMOS transistor and the second NMOS transistor are connected to each other through the second node. The first inverter and the second inverter are cascaded.

### CROSS-REFERENCE TO RELATED APPLICATION

This application claims the priority benefit of Japan application serial no. 2016-007605, filed on Jan. 19, 2016. The entirety of the above-mentioned patent application is hereby incorporated by reference herein and made a part of this specification.

### BACKGROUND OF THE INVENTION

Field of the Invention

The invention relates to a latch circuit and a semiconductor memory device having the latch circuit. The latch circuit is, for instance, configured to temporarily store data read from semiconductor memory devices. The semiconductor memory devices are electrically erasable programmable read only memories (EEPROM) (e.g., flash memories), etc.

Description of Related Art

In a known NOR-type non-volatile memory semiconductor memory device (especially a known NOR-type flash EEPROM), plural memory cell transistors (hereinafter referred to as memory cells) respectively corresponding to word lines are connected in parallel between bit lines and source lines, so as to constitute a memory cell array and achieve high integration.

FIG. 1 is a block diagram illustrating the entire structure of a conventional NOR-type flash EEPROM. In FIG. 1, the NOR-type flash EEPROM includes a memory cell array 10, a control circuit 11 controlling the operation of the memory cell array 10, a row decoder 12, a high voltage generating circuit 13, a page buffer circuit 14, a column switch circuit 15, a column decoder 16, a command register 17, an address buffer 18, an action logic controller 19, a data input/output (I/O) buffer 50, a data I/O terminal 51, a control signal input terminal 53, and an address input terminal 54. Besides, the reference number 52 represents a data line.

In order to shorten the time to charge and discharge word lines, the memory cell array 10 is divided into 2 memory banks and is set as two cell arrays CA0 and CA1. The page buffer circuit 14 has a column switch circuit 14A, a sense amplifier circuit 14B, and a latch circuit 14C. Here, the sense amplifier circuit 14B has sense amplifiers SA0-SAN amplifying sense voltages of reading data from the memory cell arrays CA0 and CA1, and the latch circuit 14C has latches L0-LN.

In FIG. 1, the row decoder 12 and the column decoder 16 are configured to select word lines WL and bit lines GBL of the memory cell array 10. The control circuit 11 controls sequence of data writing, erasing, and reading actions. The high voltage generating circuit 13 controlled by the control circuit 11 generates boosted high voltages or middle voltages that are configured to perform the data rewriting, erasing, and reading actions.

The data I/O buffer 50 is configured to input/output data. That is, data are transmitted between the I/O terminal 51 and the page buffer circuit 14 through the I/O buffer 50, the data line 52, and the column switch circuit 15. The address signal input from the address input 54 is retained at the address buffer 18 and sent to the row decoder 12 and the column decoder 16 for decoding. The decoded column selection signal is sent to the column switch circuit 15 and the column switch circuit 14A. An action control command is also input to the I/O terminal 51. The input command, after being decoded, is retained at a command register 17 for the control circuit 11 to perform control. External control signals including chip enabling signal CEB, a write-in enabling signal WEB, and an output enabling signal OEB are sent to the action logic controller 19 through the control signal I/O terminal 53, and internal control signals are generated according to an action mode. The internal control signals are configured to control data latching and transmission actions in the I/O buffer 50 and are then sent to the control circuit 11 for action control.

### PRIOR ART REFERENCES

### Patent Documents

[Patent Document 1] JP Patent Publication No. H08-213883

### [Patent Document 2] JP Patent Publication No. 2009-043357

### [Patent Document 3] US Patent Application Publication No. 2009/0091995

### Problems to be Solved by the Present Invention

FIG. 2 is a block diagram illustrating a structure of a data reading circuit in the flash EEPROM depicted in FIG. 1. In FIG. 2, the data reading circuit is included in the page buffer circuit 14 and includes the column switch circuit 14A, the sense amplifier circuit 14B, and the latch circuit 14C. Here, the data read by the page buffer circuit 14 are output to the data line 52 through the column switch circuit 15 including a multiplexer 21 and a buffer circuit 22.

As shown in FIG. 2, when data are read from the flash EEPROM, it is common to expedite the process through reading out plural bits of data at one time and sequentially outputting the data in certain cycles according to a bus width. As shown in FIG. 2, given that 256 sense amplifiers SA0-SAN (N=255) and 256 latches L0-LN (N=255), and the data line 52 has the 32-bit bus width, 256 bits of data read from the memory cell arrays CA0 and CA1 are need to output in 8 cycles.

The latches L0-LN retaining the data temporarily are put to release the sense amplifiers SA0-SAN for continuously reading the data in a seamless manner and to output the next read-out data. The sense amplifiers SA0-SAN and the latches L0-LN are not only required to perform actions in a rapid manner but also required to consume small electric current, so as to minimize the circuit size.

FIG. 3 is a circuit diagram illustrating a circuit structure of a latch circuit according to a related art. FIG. 4 is a timing chart illustrating operations of the latch circuit in FIG. 3.

The latch circuit shown in FIG. 3 includes an input circuit 30 that is configured to input a sense voltage INB from the sense amplifier SA and two inverters 31 and 32 that are cascaded. The input circuit 30 is between a positive power voltage VDD and a negative power voltage VSS and includes:

(1) a p-channel metal oxide semiconductor (PMOS) transistor Q1 that controls a signal current Isig flowing through the PMOS transistor Q1 and a PMOS transistor Q2 according to the sense voltage INB;

(2) the PMOS transistor Q2 that is switched on or off according to an inversion data enabling signal DATAENB;

(3) an n-channel MOS (NMOS) transistor Q3 that is switched on or off according to a data enabling signal DATAEN;

(4) an NMOS transistor Q4 that controls a reference current Iref flowing through the NMOS transistors Q3 and Q4 according to a bias voltage BIAS.

Note that the MOS transistors Q1-Q4 are connected in series.

A connection point between a drain of the PMOS transistor Q2 and a drain of the NMOS transistor Q3 is connected to a node N1. The inversion data enabling signal DATAENB is an inversion signal of the data enabling signal DATAEN. The positive power voltage VDD is, for instance, +3V, and the negative power voltage VSS is, for instance, 0V.

The inverter 31 is powered with the positive power voltage VDD and the negative power voltage VSS and includes:

(1) a PMOS transistor Q11 that is switched on or off according to the data enabling signal DATAEN;

(2) a PMOS transistor Q12 that is switched on or off according to a node voltage VN2 of a node N2;

(3) an NMOS transistor Q13 that is switched on or off according to the node voltage VN2 of the node N2;

(4) an NMOS transistor Q14 that is switched on or off according to the inversion data enabling signal DATAENB.

Note that the MOS transistors Q11-Q14 are connected in series. A connection point between a drain of the PMOS transistor Q12 and a drain of the NMOS transistor Q13 is connected to the node N1.

The inverter 32 is powered with the positive power voltage VDD and the negative power voltage VSS and includes:

(1) a PMOS transistor Q15 that is switched on or off according to an inversion enabling signal ENB;

(2) a PMOS transistor Q16 that is switched on or off according to a node voltage VN1 of the node N1;

(3) an NMOS transistor Q17 that is switched on or off according to the node voltage VN1 of the node N1;

(4) an NMOS transistor Q18 that is switched on or off according to the enabling signal EN.

Note that the MOS transistors Q15-Q18 are connected in series. A connection point between a drain of the PMOS transistor Q16 and a drain of the NMOS transistor Q17 is connected to the node N2. The inversion enabling signal ENB is an inversion signal of the enabling signal EN.

In said latch circuit, at the time t1 shown in FIG. 4, when the enabling signal EN and the data enabling signal DATAEN are respectively inverted, and the bias voltage is applied, the node voltage VN1 corresponding to the sense voltage INB is shifted to the corresponding potential. When the enabling signal EN and the data enabling signal DATAEN are respectively inverted at the time t2, the node voltage VN2 corresponding to the node voltage VN1 is shifted to the corresponding potential. During the flip-flop feedback period T10 from the time t3 to the time t4, each of the node voltages VN1 and VN2 is respectively shifted to the positive power voltage VDD or the negative power voltage VSS, so as to retain the data.

As described above, in the flip-flop type latch circuit, the node voltage VN2 is inverted according to the other node voltage VN1. Here, the node voltage VN1 is determined by the difference between the currents Isig and Iref, and whether the flip-flop is in an inverted state is determined by the node voltage VN1.

However, as exemplified in the patent references 1-3, the conventional latch circuits encounter issues of large consumption of electric current, large circuit size, and inability to perform operations in a rapid manner.

### SUMMARY OF THE INVENTION

The invention is directed to a latch circuit that is characterized by small consumption of electric current, small circuit size, and ability to perform actions in a rapid manner in comparison with a conventional latch circuit, and the invention is also directed to a semiconductor memory device having the latch circuit.

### Methods to Solve the Problem

In an embodiment of the invention, a latch circuit includes:

an input circuit that includes a PMOS transistor configured for input, wherein the PMOS transistor configured for input enables a signal current to flow into the PMOS transistor, and the signal current corresponds to a sense voltage from a sense amplifier;

a first inverter that includes a first PMOS transistor, a first NMOS transistor, and a first node, wherein the first PMOS transistor and the first NMOS transistor are connected to each other through the first node, and the first node is connected to the input circuit;

a second inverter that includes a second PMOS transistor, a second NMOS transistor, and a second node, wherein the second PMOS transistor and the second NMOS transistor are connected to each other through the second node,

the first inverter and the second inverter are cascaded,

the first inverter includes a third NMOS transistor and a fourth NMOS transistor, the third NMOS transistor and the fourth NMOS transistor are connected in parallel and are connected to the first NMOS transistor,

during a data latching process, the third NMOS transistor enables a reference current corresponding to a bias voltage to flow to the first inverter, and the fourth NMOS transistor is switched off during the data latching process and is switched on during a data retaining process, such that the latch circuit latches data corresponding to the sense voltage.

In the latch circuit, lengths and widths of gates of the PMOS transistor configured for input and the third NMOS transistor are greater than minimum lengths and minimum widths available for gates of the first PMOS transistor and the second PMOS transistor and greater than minimum lengths and minimum widths available for gates of the first NMOS transistor and the second NMOS transistor.

In the latch circuit, the input circuit further includes: a fifth NMOS transistor that resets a voltage of the first node in response to a reset signal.

In the latch circuit, the first inverter further includes a third PMOS transistor connected to the first PMOS transistor, and the third PMOS transistor resets the voltage of the first node in response to the reset signal.

In the latch circuit, the input circuit further includes: a fourth PMOS transistor that enables the signal current to flow according to a data enabling signal.

The latch circuit further includes a simplified inverter capable of merely inverting a voltage of the second node.

In an embodiment of the invention, the semiconductor memory device is characterized by the aforesaid latch circuit.

### Effects of the Present Invention

The invention provides a latch circuit that is characterized by small consumption of electric current, small circuit size, and ability to perform actions in a rapid manner in comparison with a latch circuit provided in the related art, and the invention is also directed to a semiconductor memory device having the latch circuit.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram illustrating the entire structure of a conventional NOR-type flash EEPROM.

FIG. 2 is a block diagram illustrating a structure of a data reading circuit in the flash EEPROM depicted in FIG. 1.

FIG. 3 is a circuit diagram illustrating a circuit structure of a latch circuit according to a related art.

FIG. 4 is a timing chart illustrating operations of the conventional latch circuit in FIG. 3.

FIG. 5 is a circuit diagram illustrating a circuit structure of a latch circuit in a flash EEPROM according to an embodiment of the invention.

FIG. 6 is a timing chart illustrating operations of the latch circuit in FIG. 5.

FIG. 7 is a circuit diagram illustrating a circuit structure of a latch circuit during simulation according to a comparison example.

### DESCRIPTION OF THE EMBODIMENTS

Hereafter, description of embodiments of the present invention will be made referring to the accompanying drawings. Moreover, the same reference numbers are used in each embodiment to refer to the same configuration elements.

Reference will now be made in detail to the present preferred embodiments of the invention, examples of which are illustrated in the accompanying drawings. Wherever possible, the same reference numbers are used in the drawings and the description to refer to the same or like parts.

FIG. 5 is a circuit diagram illustrating a circuit structure of a latch circuit in a flash EEPROM according to an embodiment of the invention. The differences between the latch circuit shown in FIG. 5 and the latch circuit shown in FIG. 3 are:

(1) a reset signal RST replacing the data enabling signal DATAEN is applied to the gate of the NMOS transistor Q3;

(2) the NMOS transistor Q14 is connected to the NMOS transistor Q15 in parallel instead of being connected to the NMOS transistor Q4, such that the NMOS transistor Q15 controls the reference current corresponding to the bias voltage BIAS;

(3) the reset signal RST replacing the data enabling signal DATAEN is applied to the gate of the PMOS transistor Q11;

(4) the PMOS transistor Q15 and the NMOS transistor 18 are deleted;

(5) the node N2 is the output terminal of the latch circuit, and an output voltage is output through the data buffer inverter 61.

According to the present embodiment, the latch circuit shown in FIG. 5 includes an input circuit 40 that is configured to input a sense voltage INB from the sense amplifier SA and two inverters 41 and 42 that are cascaded. The input circuit 40 is powered with a positive power voltage VDD and a negative power voltage VSS and includes:

(1) the PMOS transistor Q1 that controls a signal current Isig flowing through the PMOS transistors Q1 and Q2 according to a sense voltage INB;

(2) the PMOS transistor Q2 that is switched on or off according to the inversion data enabling signal DATAENB and enables the signal current Isig to flow in response to the inversion data enabling signal DATAENB;

(3) the NMOS transistor Q3 that is switched on or off according to the reset signal RST.

Note that the MOS transistors Q1-Q3 are connected in series. A connection point between a drain of the PMOS transistor Q2 and a drain of the NMOS transistor Q3 is connected to the node N1.

The inverter 41 is powered with the positive power voltage VDD and the negative power voltage VSS and includes:

(1) the PMOS transistor Q11 that is switched on or off according to the reset signal RST;

(2) the PMOS transistor Q12 that is switched on or off according to the node voltage VN2 of the node N2;

(3) the NMOS transistor Q13 that is switched on or off according to the node voltage VN2 of the node N2;

(4) the NMOS transistor Q14 and the NMOS transistor Q15 that are connected in parallel.

Note that the MOS transistors Q11-Q13 and the parallel circuits of the MOS transistors Q14 and Q15 are connected in series.

Here, the NMOS transistor Q14 is switched on or off according to the inversion data enabling signal DATAENB, and the NMOS transistor Q15 corresponding to the bias voltage BIAS controls the reference current Iref. A connection point between a drain of the PMOS transistor Q12 and a drain of the NMOS transistor Q13 is connected to the node N1.

The inverter 42 is powered with the positive power voltage VDD and the negative power voltage VSS and includes:

(1) the PMOS transistor Q16 that is switched on or off according to the node voltage VN1 of the node N1;

(2) the NMOS transistor Q17 that is switched on or off according to the node voltage VN1 of the node N1.

Note that the MOS transistors Q16 and Q17 are connected in series. A connection point between a drain of the PMOS transistor Q16 and a drain of the NMOS transistor Q17 is connected to the node N2.

Here, the node voltage VN2 as the output voltage is output through the data buffer inverter 61.

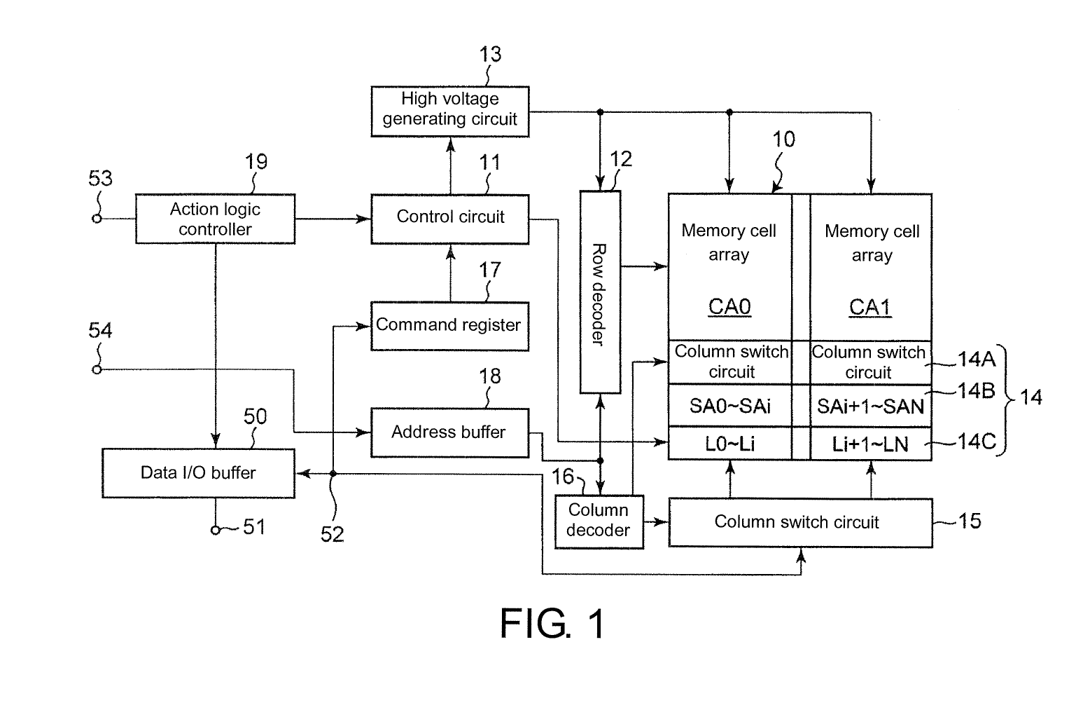

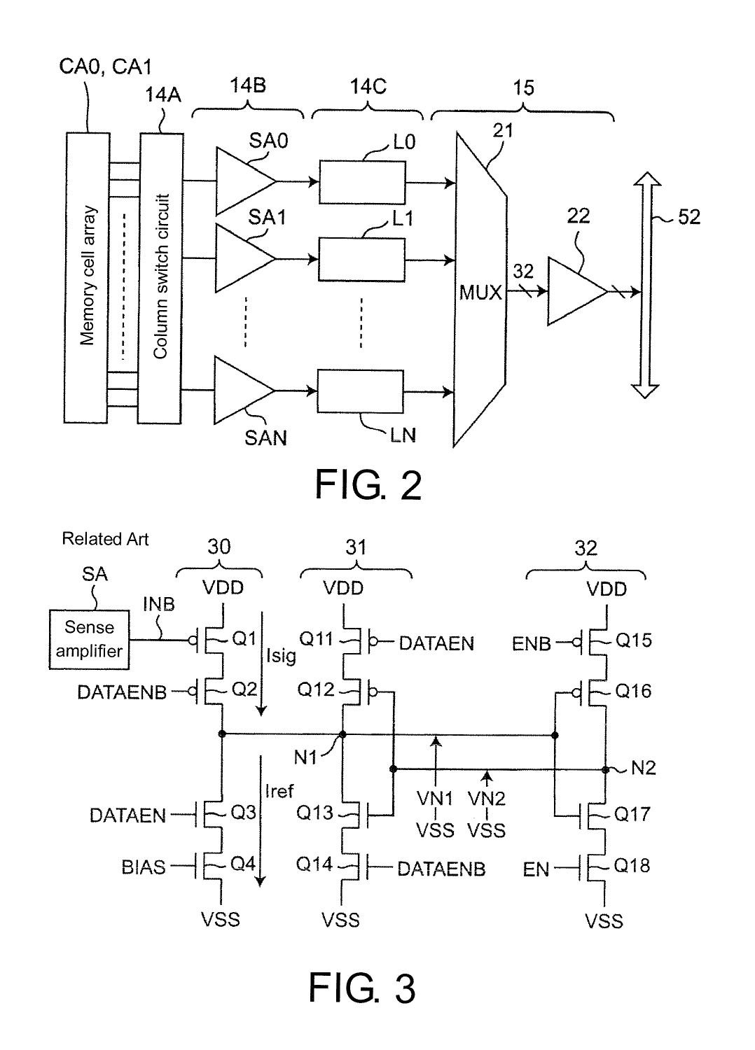

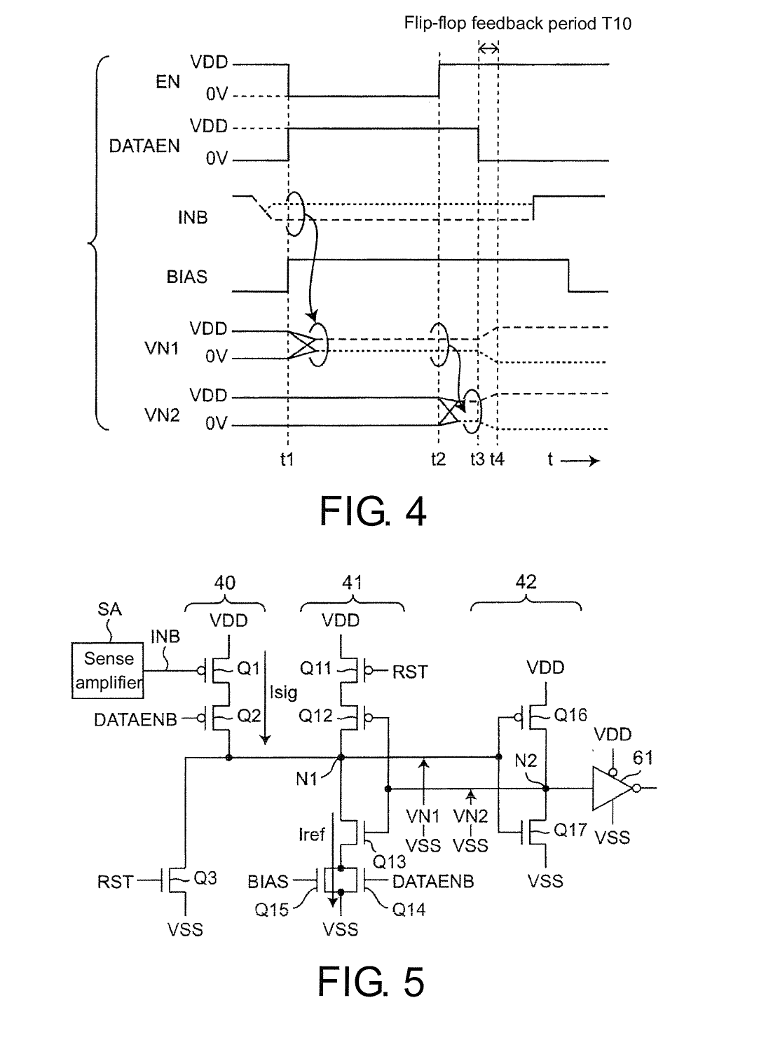

Besides, the control signal of the latch signal, i.e., the inversion data enabling signal DATAENB, the reset signal RST, and the bias voltage BIAS, are generated by the control circuit 11 (FIG. 1). In order to base on actions of analog input voltages (i.e., the sense voltage INB and the bias voltage BIAS), the lengths and the widths of the gates of the PMOS transistor Q1 and the NMOS transistor Q15 are preferably greater than the minimum available sizes (i.e., the minimum lengths and the minimum widths) of the gates of other MOS transistors Q2-Q14, Q16, and Q17. Thereby, the deviation of the current of the transistor caused by the deviation of the length or width of the gate can be reduced. Here, the deviation of the length or width of the gate results from the manufacturing process. For instance, if the minimum length of the gate is 0.1 μm, the length of the gate of the PMOS transistor Q1 and the NMOS transistor Q15 should be at least 0.3 μm, so that the 0.01-μm deviation may be reduced from 10% to 3%.

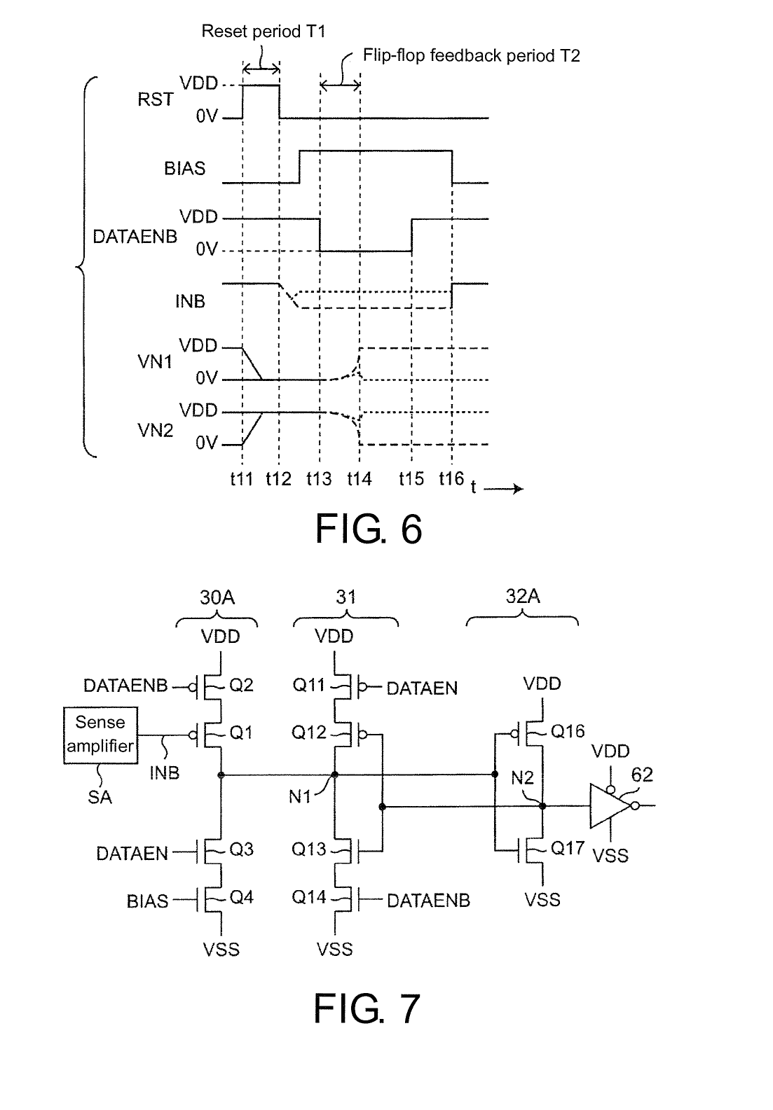

FIG. 6 is a timing chart illustrating operations of the latch circuit in FIG. 5. Before the data are latched, i.e., in the reset period Ti from the time t11 to the time t12 shown in FIG. 6 (in the data reading action, the period is from the time the data are output from the latch Li to the data line 52 to the time the sense amplifier SAi performs the next data reading action, the sense action is completed, and the data are latched), the latch circuit is reset. After reset, the node voltage VN1 becomes 0V, and the node voltage VN2 becomes the positive power voltage VDD. After that, when the bias voltage BIAS is applied at the time t13, and when the inversion data enabling signal DATAENB is inverted at the time t14, in response to the sense voltage INB coming from the sense amplifier SA, the PMOS transistor Q1 converts the sense voltage INB into the signal current Isig. Besides, in response to the bias voltage BIAS, the reference current Iref flows to the NMOS transistor Q15. Besides, the difference between the signal current Isig and the reference current Iref determines the node voltages VN1 and VN2, and thereby the latch status of the latch circuit are determined, wherein the latch circuit retains the determined data. At the time t15, the inversion data enabling signal DATAENB is inverted, the NMOS transistor Q14 is turned on, the impedance from the NMOS transistor Q13 to the negative power voltage VSS is reduced, and the stability of the flip-flop is enhanced. At the time t16, the applying of bias voltage BIAS is stopped.

In the latch circuit provided above, e.g., if the lengths and the widths of the gates of the PMOS transistor Q1 and the NMOS transistor Q15 are greater than the minimum available sizes of the gates of other MOS transistors Q2-Q14, Q16, and Q17, the deviation of the currents Isig and Iref related to the inversion of the flip-flop can be reduced in the latch circuit, and the feedback of the flip-flop allows rapid inversion of the latch.

FIG. 7 is a circuit diagram illustrating a circuit structure of a latch circuit during simulation according to a comparison example. In order to evaluate the performance of the latch circuit shown in FIG. 5, the differences between the latch circuit depicted in FIG. 7 and the latch circuit depicted in FIG. 3 according to the related art are:

(1) the input circuit 30 is replaced by an input circuit 30A where the locations of the PMOS transistors Q1 and Q2 are exchanged, wherein the exchange of the locations almost poses no impact on the evaluation of the performance;

(2) the inverter 32 is replaced by an inverter 32A where the MOS transistors Q15 and Q18 are omitted. Said settings aim at equalize the load conditions of the latch circuits in FIG. 7 and in FIG. 5. Since, when the MOS transistors Q15 and Q18 are not omitted, the simulation result showed much bigger difference for the case.

Here, the node voltage VN2 as the output voltage is output through the data buffer inverter 62.

Table 1 is a table indicating simulation results of the latch circuit depicted in FIG. 5 according to an embodiment of the invention and the latch circuit depicted in FIG. 7 according to a comparison example. Here,

(1) the size of the PMOS transistor Q1 (where the sense voltage INB is input) in the latch circuit shown in FIG. 5 is the same as the size of the PMOS transistor Q1 (where the sense voltage INB is input) in the latch circuit shown in FIG. 7;

(2) the size of the PMOS transistor Q15 (where the bias voltage BIAS is input) in the latch circuit shown in FIG. 5 is the same as the size of the PMOS transistor Q4 (where the bias voltage BIAS is input) in the latch circuit shown in FIG. 7;

(3) the sizes of other logic MOS transistors Q2, Q3, Q11-Q14, Q16, and Q17 shown in FIG. 5 are the same as those shown in FIG. 7.

TABLE 1

| | |
|---|---|
| | Consumption |
| Speed (ns) | of electric |

| | 90% rise | Fall time to | current |
|---|---|---|---|
| | time at the | 10% at the | Average |
| | node N1 | node N2 | (μA) |
| Embodiment | 2.5 | 2.4 | 9.9 |
| shown in | | | |
| FIG. 5 | | | |
| Comparison | 4.5 | 2.6 | 20.2 |
| example | | | |
| shown in | | | |
| FIG. 7 | | | |

It is clearly shown in Table 1 that the penetrating current in the latch circuit provided in FIG. 5 is significantly reduced in comparison with the penetrating current in the latch circuit provided in FIG. 7 according to the comparison example, such that the consumption of electric current during the period from reset to the inversion of the latch is reduced by half. Besides, rise-up time in the latch circuit provided in FIG. 5 is reduced by half in comparison with rise-up time in the latch circuit provided in FIG. 7.

Moreover, as shown in FIG. 6 and Table 1, the node voltages VN1 and VN2 of the flip-flop are rapidly changed, such that the data buffer inverter 61 can be not constituted by a clocked inverter which temporarily stores data in a gate capacitor according to a clock signal and cuts the penetrating current (i.e., the data buffer inverter 61 is not the clocked inverter) but constituted by a common simplified inverter that does not have any temporary data storing function and cannot cut the penetrating current. Thereby, the overall circuit size of the latch circuit can be reduced in comparison with that provided in the related art. Here, the simplified inverter can merely invert the voltage of the input signal.

Similar to the latch circuit shown in FIG. 7, in the latch circuit shown in FIG. 5, the locations of the PMOS transistors Q1 and Q2 can be exchanged. In addition, the PMOS transistor Q11 can also be omitted. Given that the PMOS transistor Q11 is omitted, the width of the gate of the PMOS transistor Q12 can be reduced by half, and thus the circuit size can be further decreased. However, it should be mentioned that the performance of the electric current of the NMOS transistor Q3 configured for reset is required to be greater than the performance of the electric current of the PMOS transistor Q12.

In the previous embodiments, the NOR-type flash EEPROM is utilized to explain the invention, which should however not be construed as limitations to the invention. Other semiconductor memory devices including different types of semiconductor memory devices can also be applicable in the invention. The different types of semiconductor memory devices are non-volatile semiconductor memory devices (e.g., flash EEPROMs), etc, and such non-volatile semiconductor memory devices can write data into floating gates, traps in an insulation membrane, or any material characterized by resistance variations.

### INDUSTRIAL APPLICABILITY

As elaborated above, the latch circuit provided herein can be characterized by small consumption of electric current, small circuit size, and ability to perform actions in a rapid manner in comparison with a conventional latch circuit.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A latch circuit comprising:
an input circuit comprising a p-channel metal oxide semiconductor transistor configured for input, wherein the p-channel metal oxide semiconductor transistor configured for input enables a signal current to flow into the p-channel metal oxide semiconductor transistor, and the signal current corresponds to a sense voltage from a sense amplifier;
a first inverter comprising a first p-channel metal oxide semiconductor transistor, a first n-channel metal oxide semiconductor transistor, and a first node, wherein the first p-channel metal oxide semiconductor transistor and the first n-channel metal oxide semiconductor transistor are connected to each other through the first node, and the first node is connected to the input circuit; and
a second inverter comprising a second p-channel metal oxide semiconductor transistor, a second n-channel metal oxide semiconductor transistor, and a second node, wherein the second p-channel metal oxide semiconductor transistor and the second n-channel metal oxide semiconductor transistor are connected to each other through the second node,
the first inverter and the second inverter are cascaded each other,
the first inverter comprises a third n-channel metal oxide semiconductor transistor and a fourth n-channel metal oxide semiconductor transistor, the third n-channel metal oxide semiconductor transistor and the fourth n-channel metal oxide semiconductor transistor are connected in parallel and are connected to the first n-channel metal oxide semiconductor transistor,
during a data latching process, the third n-channel metal oxide semiconductor transistor enables a reference current corresponding to a bias voltage to flow to the first inverter, and the fourth n-channel metal oxide semiconductor transistor is switched off during the data latching process and is switched on during a data retaining process, such that the latch circuit latches data corresponding to the sense voltage.

2. The latch circuit of claim 1, wherein
lengths and widths of gates of the p-channel metal oxide semiconductor transistor configured for input and the third n-channel metal oxide semiconductor transistor are greater than minimum lengths and minimum widths limited by semiconductor design rules for gates of the first p-channel metal oxide semiconductor transistor and the second p-channel metal oxide semiconductor transistor and greater than minimum lengths and minimum widths limited by semiconductor design rules for gates of the first n-channel metal oxide semiconductor transistor and the second n-channel metal oxide semiconductor transistor.

3. The latch circuit of claim 1, wherein
the input circuit further comprises:
a fifth n-channel metal oxide semiconductor transistor resetting a voltage of the first node in response to a reset signal.

4. The latch circuit of claim 1, wherein
the first inverter further comprises:
a third p-channel metal oxide semiconductor transistor connected to the first p-channel metal oxide semiconductor transistor, and the third p-channel metal oxide semiconductor transistor resets the voltage of the first node in response to the reset signal.

5. The latch circuit of claim 1, wherein
the input circuit further comprises:
a fourth p-channel metal oxide semiconductor transistor enabling the signal current to flow according to a data enabling signal.

6. The latch circuit of claim 1, further comprising:
a simplified inverter coupled to the second inverter, receiving a voltage from the second node of the second inverter and inverting the voltage of the second node to output an output voltage.

7. A semiconductor memory device comprising:
the latch circuit of claim 1.
